(19) United States
(12) Patent Application Publication
(10) Pub. No.: US 2003/0108409 A1
(43) Pub. Date: Jun. 12, 2003

(54) Method for charging and discharging a process tank

(76) Inventors: Thomas Rodewaldt, Herxheim (DE); Felix Wehrle, Sonnenb?uuml;hl (DE)

Correspondence Address: Robert W Becker & Associates, 707 Highway East Suite B, Tijieras, NM, 87059-7382, US

(21) Appl. No.: 10/240,618

(22) PCT Filed: Mar. 29, 2001
(86) PCT No.: PCT/EP01/03577

(30) Foreign Application Priority Data
Apr. 5, 2000 (EP) 100 17 101.2

(51) Int. Cl. H01L 21/00

(52) U.S. Cl. 414/416.01

(57) ABSTRACT

The invention relates to a method for charging and discharging a process tank. The aim of the invention is to simplify the charging and discharging of a process tank with disc-shaped substrates. To this end, the disc-shaped substrates are picked-up during charging by a gripper that comprises at least two opposite gripper elements with receiving slots facing one another. The substrates are positioned above the process tank in such a manner that they are aligned with guide slots within the process tank. The gripper is lowered so as to partially lower the substrates into the process tank until they contact a lifted substrate lifting element inside the process tank. The gripper elements are then moved apart into a position in which the substrates are no longer held but are still guided in the receiving slots and they are further lowered into the process tank by lowering the lifting element. For discharging the substrates, a gripper that comprises at least two opposite gripper elements with receiving slots facing one another is positioned above the process tank in such a manner that the guide slots in the tank and the receiving slots in the gripper elements are aligned with one another. The substrates are then lifted by the substrate lifting element and introduced into the receiving slots of the gripper elements. When a predetermined position is reached, the gripper elements are moved towards one another in order to grip the substrates and the substrates are lifted out of the process tank by lifting the gripper.

The present invention relates to a method for the loading of a processing tank with disk-shaped substrates, especially semiconductor substrates, as well as a method for the unloading of disk-shaped substrates, especially semiconductor wafers, from a processing tank.

In the semiconductor industry it is known that semiconductor wafers must be subjected to different treatment or processing steps that take place at least partially in processing tanks. During the processing, the semi-conductor wafers are customarily received in wafer holders that can be raised in order to hold the wafers in a predetermined orientation in the tank. The raisable wafer holders are also used for the loading and unloading of the wafers. However, such wafer holders have various drawbacks, such as, for example, a large volume, which leads to large processing tanks. Furthermore, there exists the danger that when the wafer holder is raised out of the processing tank, liquid adheres to the contact locations between wafer and wafer holder, which adversely affects the further processing of the wafer. Furthermore such wafer holders disrupt the flow conditions within the processing tank, which can adversely affect the homogeneity of the substrate processing. One example for a system where the semiconductor wafer is introduced into and raised out of a processing tank with a wafer holder is illustrated in U.S. Pat. No. 5,370,142.

With a further type of processing tank, guide slots are provided in the side walls of the tank for receiving and guiding semiconductor wafers. To provide a support of the wafers in the vertical direction, a generally centrally arranged lifting element in the form of a blade-like element or bar is provided via which the wafers are lowered and raised in the tank. For the loading and unloading of such a processing tank, there is provided a transport hood having guide slots that correspond to the guide slots in the processing tank. A locking mechanism within the hood is in a position to fix the wafers in the hood. During the loading of the processing tank, the hood, which was previously loaded with wafers, is moved over the tank and the lifting element is raised and brought into contact with the wafers. The locking or fixation is subsequently released, and the lifting element is lowered, whereby the wafers are initially guided by the guide slots in the hood and subsequently by the guide slots in the tank. One example for such a system is illustrated in DE-A-196 52 526, which originates with this same applicant.

This system has the drawback that first the hood must be loaded in order to subsequently load the processing tank. Furthermore, after the unloading of the processing tank the hood must again itself be unloaded, which considerably increases the handling complexity of the processing system. Furthermore, the construction of the hood is relatively large and cumbersome. Furthermore, the hood has a problem that gases that rise out of the processing tank collect in the hood and are deposited against the side walls of the hood. A handling of substrates that are wetted with processing liquid and which is necessary in the treatment sequence is not possible with the hood, since the processing liquid would then also wet the hood itself as well as the guide slots disposed therein. Due to the construction of the hood, the processing liquid cannot be removed from the hood. This leads to contamination of the wafers and/or of subsequent processing regions.

DE-A-196 378 75 shows a unit for the wet treatment of substrates in a tank that contains a processing fluid. With this unit, the substrates are placed into the tank with a substrate carrier. During the removal, there is effected an alignment and centering of the substrates in the tank by means of a substrate receiving device that is provided in the tank. During the removal, the substrates are moved into a hood that is moved over the tank and that is provided with lateral guide slots, whereby the lateral guide slots in the hood are aligned with guide devices of the substrate receiving device.

A wafer cleaning apparatus is furthermore known from JP-A-052 706 60, according to which the wafers are introduced via a wafer gripper into a tank that is filled with treatment fluid. The wafer holder is introduced with the wafers into the processing tank, and the wafers are transferred to a receiving means that is stationarily provided in the processing tank, with this being accomplished by opening the gripper. During the processing, the gripper is moved out of the processing tank, and unloading of the wafers is effected in a reverse manner.

Reference is further made to JP 05 338 794, which is provided with a wafer gripper having two oppositely disposed gripper arms with guides for receiving the wafers. The guides in the gripper arms are made of a material that is softer than that of the wafers in order to prevent the substrates from becoming damaged by friction between the guides and the substrates.

Proceeding from the above mentioned state of the art, it is an object of the present invention to simplify the handling of substrates, in particular the loading and unloading of disk-shaped substrates into and out of a processing tank, and to reduce the danger of contamination of the substrates.

Pursuant to the invention, this object is realized with a method for the loading of a processing tank with disk-shaped substrates, especially semiconductor wafers, via the following method steps: grasping the substrates with a gripper that is provided with at least two oppositely disposed gripper elements having facing receiving slots; positioning the substrates over the processing tank in such a way that the substrates are aligned relative to guide slots within the processing tank; lowering the gripper for the partial lowering of the substrates into the processing tank until the substrates contact a raised substrate-lifting element in the processing tank; partially moving the gripper elements apart into a position in which the substrates are no longer held yet are still guided in the receiving slots; further lowering the substrates into the processing tank by lowering the lifting element. With this method, it is possible in a straightforward manner to directly load a processing tank having lateral guide slots by means of a substrate gripper. Since the gripper elements of the substrate gripper are controlled in such a way that they provide a guidance of the substrates during the lowering into the processing tank by means of the lifting element, the danger of a tilting and damage to the substrates is avoided. The gripper can have a simple construction, and due to the fact that no closed hood having side walls is provided, the danger of contamination to the wafers is greatly reduced.

To ensure a guidance of the substrates by the gripper for as long a time as possible, the gripper elements preferably follow the contour of the substrates. For as smooth a transition as possible between the guidance by the gripper elements and the guidance by the guide slots within the tank, the gripper elements are lowered upon an upper edge of the tank or into a position directly above the edge.

The inventive object is also realized with a method for the unloading of disk-shaped substrates, especially semiconductor wafers, out of the processing tank with a substrate-lifting element and guide slots in the tank in that a gripper, that is provided with at least two oppositely disposed gripper elements having facing receiving slots, is positioned above the processing tank in such a way that guide slots in the tank, and the receiving slots in the gripper elements, are aligned with one another; the substrates are raised and introduced into the receiving slots of the gripper elements; the gripper elements for the grasping of the substrates are moved toward one another; and the substrates are subsequently raised out of the processing tank by raising the gripper. With this unloading process, a gripper having a simple form can be used, and the gripper also has no large surfaces on which contaminations adhere that can be transferred to the substrates.

To provide as early a guidance of the substrates as possible during the raising thereof by means of the substrate-lifting element, the gripper elements follow the contour of the substrates. During the raising of the substrates, the gripper elements are preferably positioned on or just above an upper edge of the processing tank. For a reliable holding of the substrates, the gripper preferably grasps the substrates below their centerline.

The invention will be described in greater detail subsequently with the aid of a preferred exemplary embodiment in conjunction with the drawings. Shown are:

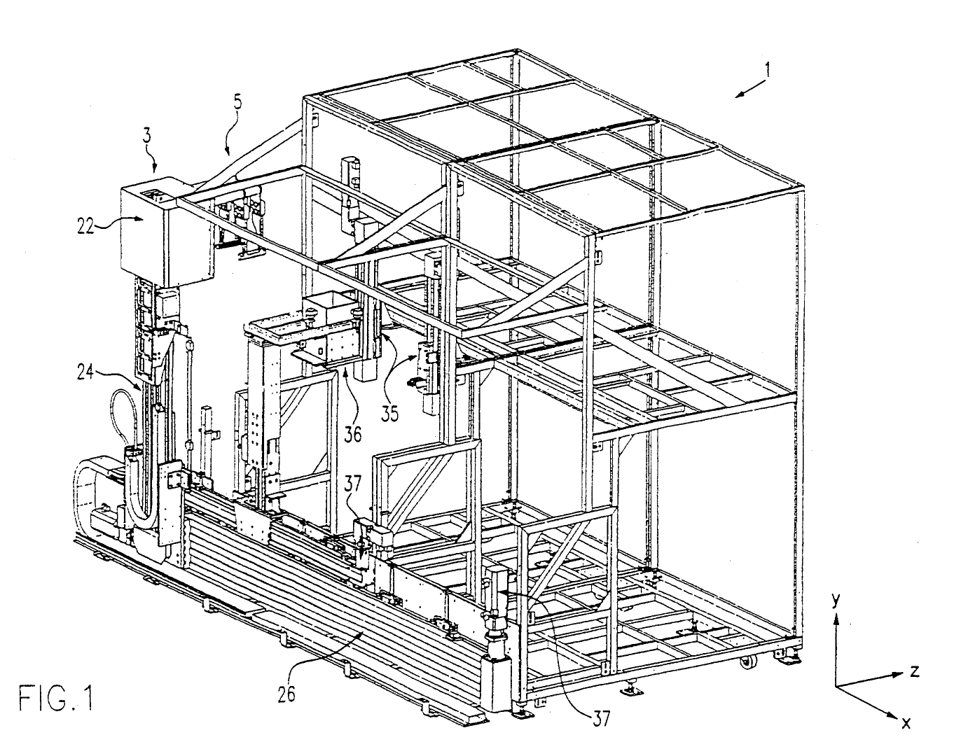

FIG. 1 a perspective view of a wafer-processing apparatus, whereby for the simplification of the illustration certain components have been omitted;

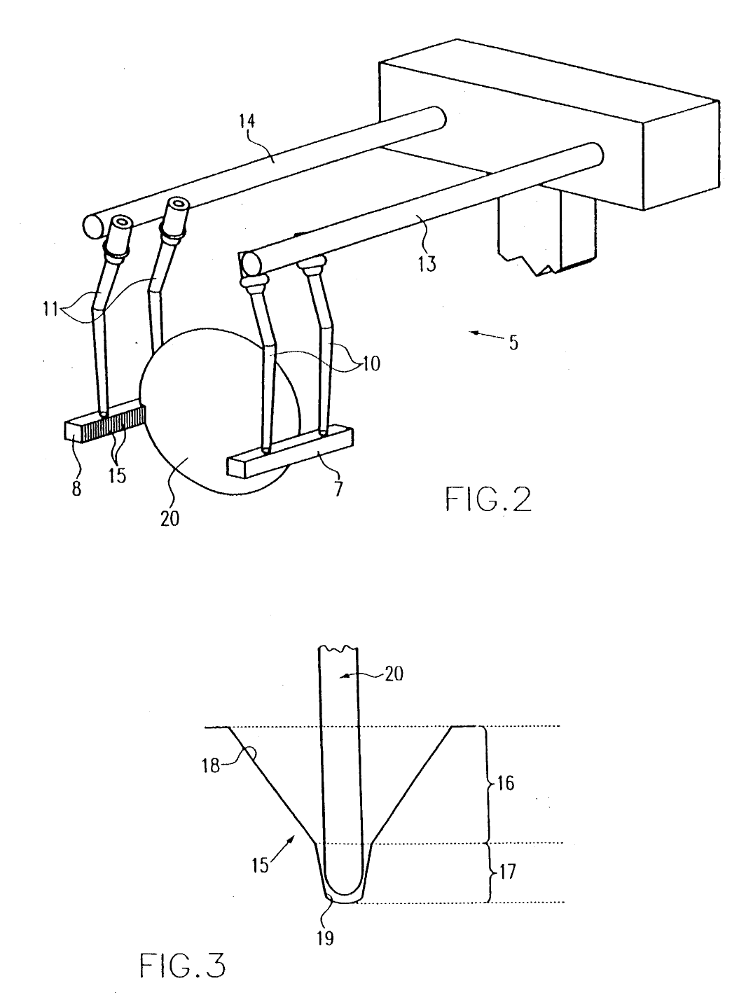

FIG. 2 a perspective view of a substrate gripper that is used during the method of the present invention;

FIG. 3 a schematic illustration of slots in toothed racks of the substrate gripper;

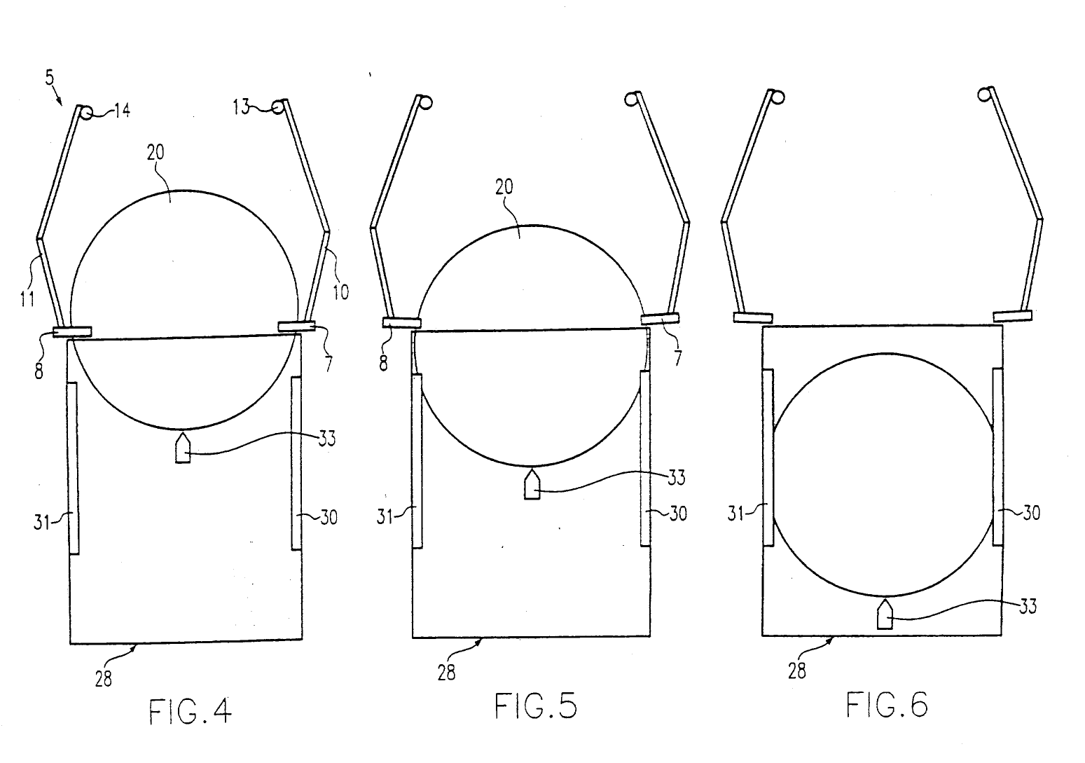

FIGS. 4,5, and 6 different method steps during the loading of a semiconductor wafer into a processing tank.

FIG. 1 shows an apparatus 1 for the processing of semiconductor wafers. The apparatus is provided with a wafer handling device 3 having a gripper 5, which can be recognized best in FIG. 2.

The gripper 5 is formed by two toothed racks 7,8 that are disposed essentially horizontally and that are secured via respective arms 10,11 on rotatable shafts 13,14. The toothed racks 7 are provided with receiving slots 15 for receiving and guiding semiconductor wafers 20. The receiving slots 15 of the toothed racks 7 and 8 face one another and are provided with a guiding and centering region 16 as well as a holding region 17, as can be recognized best in FIG. 3. The guiding and centering region 16 is provided with inclined surfaces 18 that run toward one another and along which the semiconductor wafers can glide in order to achieve a centering relative to the receiving slot 15. The holding region 17 directly adjoins the guiding and centering region 16, and in particular at that location where the inclined surfaces 18 are disposed the closest to one another. The holding region 17 is similarly provided with inclined surfaces 19 that run toward one another. The inclined surfaces 19 run toward one another at a more acute angle than do the inclined surfaces 18. The holding region of the receiving slots 15 ensure a narrow and precise guidance as well as a reliable holding of the wafers 20. By rotating the respective shafts 13,14, the toothed racks 7,8 are movable toward and away from one another, as will be described in greater detail subsequently.

For the rotation of the shafts 13,14, a drive unit 22 is provided that can be recognized best in FIG. 1. The gripper 5 is furthermore movable vertically and horizontally, and in particular via appropriate movement mechanisms that are disposed on a vertically extending rail 24 and on a horizontally extending guide rail 26 respectively. The apparatus 1 is furthermore provided with a plurality of processing tanks, which for the simplification of the illustration in FIG. 1 are not shown.

However, the FIGS. 4 to 6 schematically show treatment or processing tanks 28. The processing tanks can be filled with a treatment fluid via non-illustrated lines.

Provided on oppositely disposed inner walls of the processing tank 28 are guide projections 30,31 that extend into the interior of the tank and that form between them guide slots for receiving and guiding the semiconductor wafers. Furthermore disposed within the tank 28 is a lifting element 33 in the form of a blade-like element or bar that is displaceably carried in the vertical direction. Illustrated in FIG. 1 are vertical guide rails 35 for two lifting elements 33 disposed in different processing tanks.

The apparatus 1 illustrated in FIG. 1 is provided with a hood 36 that can be placed over the non-illustrated processing tank, and that is movable via suitable vertical and horizontal guide rails of the apparatus. The hood 36 is used if the wafer is dried after a treatment in one of the tanks pursuant to the Marangoni process.

The movement of the gripper 5 or the hood 36 is effected via suitable drive units, such as, for example, servomotors 37.

The inventive loading of the processing tank 28 with semiconductor wafers 20 will be described subsequently with the aid of FIGS. 4 to 6.

A number of semiconductor wafers 20 are first grasped by the gripper 5. In so doing, the wafers 20 are received and laterally guided in the holding regions 17 of the receiving slots 15 of the toothed racks 7,8.

The gripper 5 is subsequently moved over the processing tank 28 in such a way that the wafers 20 are aligned with guide slots formed between the guide elements 30,31. The gripper 5 is subsequently lowered into the position illustrated in FIG. 4 in which the toothed racks 7,8 are disposed just above an upper edge of the processing tank 28. In this connection, the wafers 20 are partially introduced into the processing tank 28. The lifting element 33 is in a raised position and contacts the wafers 20 at a low point.

By rotating the respective shafts 13,14, the toothed racks 7,8 are now moved apart from one another, so that the wafers 20 are moved out of the holding regions 17 of the receiving slots 15, and are thus no longer held by the gripper 5, but rather rest with their entire weight upon the lifting element 3. In this connection, however, the toothed racks 7,8 are moved apart only to such an extent that the wafers 20 are still received and guided in the guiding and centering regions 16 of the receiving slots 15.

The lifting element 33 is subsequently lowered, as a result of which the wafers 20 are also lowered into the processing tank 28. FIG. 5 shows one exemplary intermediate position of the lifting element 33 during the lowering process. As can be readily recognized in FIG. 4, the wafers 20 continue to be guided by the toothed racks 7,8. At the same time, however, the wafers 20 are also already guided by the guide slots formed between the guide projections 30,31.

FIG. 6 shows a completely lowered position of the wafers 20, in which they rest upon the lifting element 33 and are guided only by the guide projections 30,31 in the processing tank.

Although this is not illustrated in the Figures, as soon as the wafers 20 are guided by the guide projections 30,31 in the tank 28, the gripper 5 can be pivoted out further and moved out of the region of the processing tank, for example in order to load or unload a further processing tank.

During the lowering of the lifting element 33, it is possible to control the toothed racks 7,8 in such a way that they follow the contour of the wafers 20, i.e. that in conformity with the wafer contour, the toothed racks 7,8 are moved toward or away from one another. This provides a particularly long guidance by means of the toothed racks 7,8 during the lowering of the wafers. Therefore, the guide elements 30,31 within the processing tank 28 can be reduced to a minimum, which improves the flow conditions in the tank.

The unloading of the processing tank 28 is effected in the reverse manner from the loading. Thus, the gripper 5 is first moved into the position shown in FIG. 6 over the tank 28, whereby the guide regions 16 of the receiving slots 15 of the toothed racks 7,8 are aligned with the guide slots in the processing tank. The wafers are subsequently raised via the lifting element 33 and are received into the guide regions 16, whereby due to the conically embodied guide surfaces a centering of the wafers 20 relative to the receiving slots 15 of the toothed racks 7,8 is effected, as illustrated in FIG. 4. When the wafers have been raised to such an extent that the toothed racks 7,8 are disposed in a predetermined position, for example below a centerline of the wafers 20, they are moved toward one another in order to introduce and grasp the wafers 20 in the holding region 17 of the receiving slots, as illustrated in FIG. 3. The gripper 5 is subsequently raised in order to raise the wafers 20 entirely out of the tank 28.

The invention was previously described with the aid of one preferred exemplary embodiment, without, however, being limited to the specially illustrated embodiment. In particular, the form of the gripper 5 can deviate from that illustrated. For example, it is not necessary that the toothed rack 7,8 be pivoted via the shafts 13,14 and the connecting arms 10,11. Rather, it is also possible to linearly move the toothed racks 7,8 toward and away from one another.

1. Method for the loading of a processing tank with disk-shaped substrates, especially semiconductor wafers, having the following method steps:
Grasping the substrates with a gripper that has at least two oppositely disposed gripper elements having facing receiving slots;
Positioning the substrates over the processing tank in such a way that the substrates are aligned with guide slots within the processing tank;
Lowering the gripper for the partial lowering of the substrates into the processing tank until the substrates contact a raised substrate-lifting element in the processing tank;
Partially moving the gripper elements apart into a position in which the substrates are no longer held yet are still guided in the receiving slots;
Further lowering the substrates into the processing tank by lowering the lifting element.

2. Method according to claim 1, characterized in that during the further lowering of the substrates, the gripper elements follow the contour of the substrates.

3. Method according to claim 1 or 2, characterized in that the gripper elements are lowered upon an upper edge of the tank or into a position directly above the upper edge.

4. Method according to one of the claims 1 to 3, characterized in that during the grasping the substrates are centered relative to the receiving slots.

5. Method for the unloading of disk-shaped substrates, especially semiconductor wafers, out of a processing tank having a substrate-lifting element and guide slots in the tank, whereby the method has the following method steps:
Positioning a gripper, which has at least two oppositely disposed gripper elements having facing receiving slots, over the processing tank in such a way that the guide slots in the tank and the receiving slots in the gripper elements are aligned with one another;
Raising the substrates via the substrate-lifting element and introducing them into the receiving slots of the gripper element;
Moving the gripper elements toward one another in order to grasp the substrate;
Raising the substrates out of the processing tank by raising the gripper.

6. Method according to claim 5, characterized in that the gripper elements follow the contour of the substrates during the raising of the substrates via the substrate-lifting element.

7. Method according to claim 5 or 6, characterized in that the gripper elements are positioned on or slightly above an upper edge of the processing tank during the raising of the substrates.

8. Method according to one of the claims 5 to 7, characterized in that the grippers grasp the substrates below their centerline.

9. Method according to one of the claims 5 to 8, characterized in that during the introduction into the receiving slots, the substrates are centered relative to the receiving slots.
